(19) United States
(12) Patent Application Publication
(10) Pub. No.: US 2020/0358590 A1
(43) Pub. Date: Nov. 12, 2020

(54) SIGNAL RECEIVING CIRCUIT, SEMICONDUCTOR APPARATUS AND SEMICONDUCTOR SYSTEM INCLUDING THE SIGNAL RECEIVING CIRCUIT AND SEMICONDUCTOR APPARATUS

(71) Applicant: SK hynix Inc., Icheon-si Gyeonggi-do (KR)

(72) Inventor: Min Chang KIM, Seoul (KR)

(73) Assignee: SK hynix Inc., Icheon-si Gyeonggi-do (KR)

(21) Appl. No.: 16/696,658

(22) Filed: Nov. 26, 2019

(30) Foreign Application Priority Data
May 10, 2019 (KR) 10-2019-0054909

(51) Int. Cl. H04L 7/00; H03K 3/0233; H04L 25/03

(52) U.S. Cl. CPC H04L 7/0045; H04L 25/03057; H04L 7/0087; H03K 3/0233

(57) ABSTRACT

A signal receiving circuit includes a summing circuit, a clocked latch circuit and a feedback circuit. The summing circuit generates a summing signal based on an input signal and a feedback signal. The clocked latch circuit generates a sampling signal by sampling the summing signal in synchronization with a clock signal. The feedback circuit generates the feedback signal by selecting one among a plurality of coefficients based on the sampling signal.

### CROSS-REFERENCES TO RELATED APPLICATION

The present application claims priority under 35 U.S.C. § 119(a) to Korean application number 10-2019-0054909, filed on May 10, 2019, in the Korean Intellectual Property Office, which is incorporated herein by reference in its entirety as set forth in full.

### BACKGROUND

### 1. Technical Field

Various embodiments of the present disclosure generally relate to an integrated circuit technology and, more particularly, to a semiconductor apparatus and a semiconductor system.

### 2. Related Art

An electronic device includes a lot of electronic elements, and a computer system includes lots of electronic components each comprising a semiconductor. Semiconductor apparatuses configuring a computer system may communicate with each other by transmitting and receiving a clock signal and data. As an operation speed of a computer system increases, an operation speed of a semiconductor apparatus also increases. For example, a frequency of a clock signal becomes greater for semiconductor apparatuses to perform a high-speed data communication with each other.

A semiconductor apparatus may transmit data to an external apparatus in synchronization with a clock signal or may receive data from an external apparatus in synchronization with the clock signal. As a frequency of the clock signal increases, a margin of time for transmission or reception of data is reduced. Also, an “eye” and/or valid window of transmitted or received data is also reduced in proportion to the reduction of the time margin. The semiconductor apparatus is coupled to the external apparatus through a signal transmission line. When a signal is transferred through the signal transmission line, signal integrity may be reduced due to reflection of the signal occurring at the signal transmission line. Therefore, a decision feedback equalizer may be used in general to compensate for a post cursor element caused by the reflection of the signal for increase of the “eye” and/or the valid window of the signal.

### SUMMARY

In an embodiment, a signal receiving circuit may include a summing circuit, a clocked latch circuit, and a feedback circuit. The summing circuit may be configured to generate a summing signal based on an input signal and a feedback signal. The clocked latch circuit may be configured to generate a sampling signal by sampling the summing signal in synchronization with a clock signal. The feedback circuit may be configured to select one between a first coefficient and a second coefficient based on the sampling signal and configured to generate the feedback signal based on a selected coefficient and the sampling signal.

In an embodiment, a signal receiving circuit may include a receiver, a comparison circuit, a clocked latch circuit, and a feedback circuit. The receiver may be configured to generate an input signal based on a transmission signal transmitted through a signal bus. The comparison circuit may be configured to change a voltage level of a first summing node based on a voltage level of the input signal and configured to change a voltage level of a second summing node based on a voltage level of a reference voltage. The clocked latch circuit may be configured to generate a sampling signal by latching the voltage levels of the first summing node and the second summing node in synchronization with a clock signal. The feedback circuit may be configured to select one between a first coefficient and a second coefficient based on the sampling signal and configured to change the voltage levels of the first summing node and the second summing node based on a selected coefficient and the sampling signal.

In an embodiment, a signal receiving circuit may include a receiver, a summing circuit, a clocked latch circuit, and a feedback circuit. The receiver may be configured to generate an input signal based on a transmission signal transmitted through a signal bus. The summing circuit may be configured to generate a summing signal based on the input signal and a feedback signal. The clocked latch circuit may be configured to generate a first sampling signal by sampling the summing signal in synchronization with a first phase clock signal. The feedback circuit may be configured to select one between a first coefficient and a second coefficient based on a second sampling signal, which is generated in synchronization with a second phase clock signal having a phase leading the first phase clock signal, and configured to generate the feedback signal based on a selected coefficient and the second sampling signal.

### BRIEF DESCRIPTION OF THE DRAWINGS

FIG. 1 is a diagram illustrating a configuration of a semiconductor system in accordance with an embodiment;

FIG. 2A is a diagram illustrating a configuration of a semiconductor system and a characteristic of an electrical current of a transmission circuit under a symmetric interface circumstance;

FIG. 2B is a diagram illustrating a waveform of an input signal generated by a receiver illustrated in FIG. 2A;

FIG. 3A is a diagram illustrating a configuration of a semiconductor system and a characteristic of an electrical current of a transmission circuit under an asymmetric interface circumstance;

FIG. 3B is a diagram illustrating a waveform of an input signal generated by a receiver illustrated in FIG. 3A;

FIG. 4 is a diagram illustrating a configuration of a signal receiving circuit in accordance with an embodiment;

FIG. 5 is a diagram illustrating a configuration of a decision feedback equalization circuit in accordance with an embodiment;

FIGS. 6 and 7 are diagrams illustrating a summing signal when an equalization operation is performed with a single coefficient under an asymmetric interface circumstance;

FIG. 8 is a diagram illustrating a summing signal when an equalization operation is performed with different coefficients in accordance with an embodiment;

FIG. 9 is a diagram illustrating a configuration of a decision feedback equalization circuit in accordance with an embodiment; and

FIG. 10 is a diagram illustrating a configuration of a semiconductor apparatus in accordance with an embodiment.

### DETAILED DESCRIPTION

Hereinafter, a semiconductor apparatus according to the present disclosure will be described below with reference to the accompanying drawings through examples of embodiments.

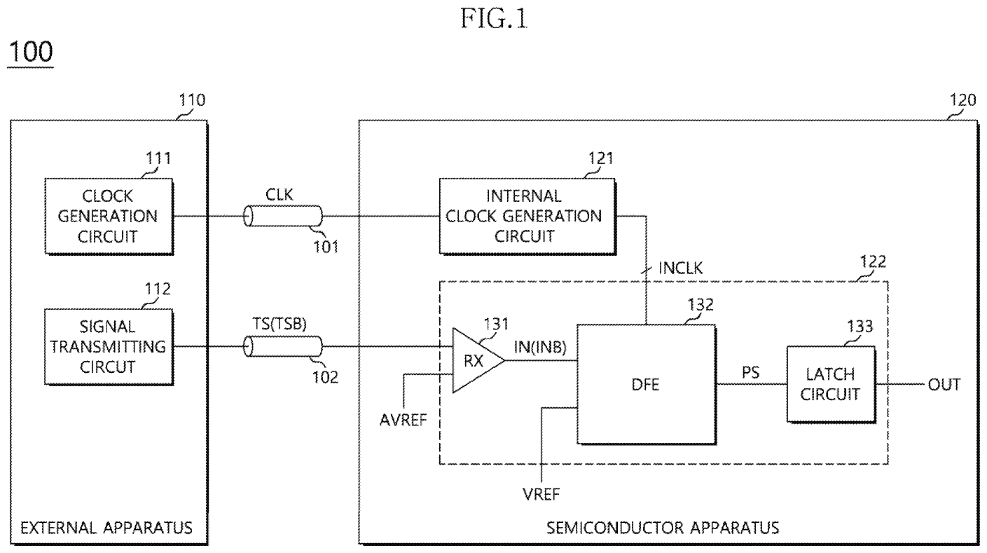

FIG. 1 is a diagram illustrating a configuration of a semiconductor system 100 in accordance with an embodiment. Referring to FIG. 1, the semiconductor system 100 may include an external apparatus 110 and a semiconductor apparatus 120. The external apparatus 110 may provide various control signals required for the semiconductor apparatus 120 to perform operations. The external apparatus 110 may include apparatuses of various types. For example, the external apparatus 110 may be a host such as a central processing unit (CPU), a graphic processing unit (GPU), a multi-media processor (MMP), a digital signal processor, an application processor (AP) and a memory controller. Also, the external apparatus 110 may be a test apparatus or a test equipment for testing the semiconductor apparatus 120. For example, the semiconductor apparatus 120 may be a memory apparatus and the memory apparatus may include a volatile memory and a non-volatile memory. The volatile memory may include a static random access memory (static RAM: SRAM) and a dynamic RAM (DRAM), a synchronous DRAM (SDRAM). The non-volatile memory may include a read only memory (ROM), a programmable ROM (PROM), an electrically erasable and programmable ROM (EEPROM), an electrically programmable ROM (EPROM), a flash memory, a phase change RAM (PRAM), a magnetic RAM (MRAM), a resistive RAM (RRAM), a ferroelectric RAM (FRAM) and so forth.

The semiconductor apparatus 120 may be electrically coupled to the external apparatus 110 functioning as a test equipment and may perform a test operation. The semiconductor apparatus 120 may be electrically coupled to the external apparatus 110 functioning as a host apparatus and may perform various operations other than the test operation. For example, the semiconductor apparatus 120 may be electrically coupled to the external apparatus 110 functioning as a test equipment and may be tested after fabrication of the semiconductor apparatus 120. The semiconductor apparatus 120 may be electrically coupled to the external apparatus 110 functioning as a host apparatus and may perform various operations after completion of the test.

The semiconductor apparatus 120 may be electrically coupled to the external apparatus 110 through a plurality of buses. Each of the plurality of buses may be a signal transmission path, a link or a channel for transferring a signal. The plurality of buses may include a first bus 101 and a second bus 102. The first bus 101 may be a one-way bus or a two-way bus. The second bus 102 may be a two-way bus. The semiconductor apparatus 120 may be electrically coupled to the external apparatus 110 through the first bus 101 and may receive a clock signal CLK through the first bus 101. The clock signal CLK may include one or more pairs of clock signals. In an embodiment, a transmission signal TS may be transferred in synchronization with the clock signal CLK and may be data for example. The clock signal CLK may include a data clock signal and/or a data strobe signal. The semiconductor apparatus 120 may be electrically coupled to the external apparatus 110 through the second bus 102 and may receive the transmission signal TS from the external apparatus 110 through the second bus 102 or may transmit the transmission signal TS to the external apparatus 110 through the second bus 102. The transmission signal TS may be transmitted as a single ended signal or may be transmitted, as a differential signal, together with a complementary signal TSB.

The external apparatus 110 may include a clock generation circuit 111 and a signal transmitting circuit 112. The clock generation circuit 111 may generate the clock signal CLK. The clock generation circuit 111 may drive the first bus 101 thereby transmitting the clock signal CLK through the first bus 101. The clock generation circuit 111 may include a clock generator such as a phase locked loop circuit. The signal transmitting circuit 112 may output the transmission signal TS based on an internal signal of the external apparatus 110. The signal transmitting circuit 112 may drive the second bus 102 based on the internal signal thereby transmitting the transmission signal TS through the second bus 102.

The semiconductor apparatus 120 may include an internal clock generation circuit 121 and a signal receiving circuit 122. The internal clock generation circuit 121 may be electrically coupled to the first bus 101 and may generate a plurality of internal clock signals INCLK by receiving the clock signal CLK through the first bus 101. The semiconductor apparatus 120 may receive and/or sample the transmission signal TS, which is transferred through the second bus 102, in synchronization with the clock signal CLK. In an embodiment, the semiconductor apparatus 120 may divide the clock signal CLK and may use the divided clocks in order to sufficiently secure a timing margin for receiving and/or sampling the transmission signal TS. The internal clock generation circuit 121 may divide the frequency of the clock signal CLK and may generate the plurality of internal clock signals INCLK having different phases.

The signal receiving circuit 122 may be electrically coupled to the second bus 102 and may receive the transmission signal TS, which is transferred from the external apparatus 110, through the second bus 102. The signal receiving circuit 122 may receive the plurality of internal clock signals INCLK generated by the internal clock generation circuit 121. The signal receiving circuit 122 may receive the transmission signal TS based on the plurality of internal clock signals INCLK. The signal receiving circuit 122 may receive the transmission signal TS, which is transferred from the external apparatus 110, in synchronization with the plurality of internal clock signals INCLK.

The signal receiving circuit 122 may include a receiver 131 and a decision feedback equalization circuit 132. The receiver 131 may be electrically coupled to the second bus 102, may receive the transmission signal TS and may generate an input signal IN based on the transmission signal TS. The receiver 131 may include an amplifier configured to differentially amplify the transmission signal TS. The receiver 131 may generate the input signal IN by comparing the transmission signal TS with an amplification reference voltage AVREF. In an embodiment, the receiver 131 may generate the input signal IN by differentially amplifying the transmission signal TS and the complementary signal TSB. In an embodiment, the receiver 131 may perform an equalization operation on the input signal IN, which is generated on the basis of the transmission signal TS. The receiver 131 may include a Continuous Time Linear Equalizer (CTLE) capable of performing an equalization operation. The receiver 131 may output, together with the input signal IN, a complementary signal INB of the input signal IN.

The decision feedback equalization (DFE) circuit 132 may receive the input signal IN and may generate a sampling signal PS. The decision feedback equalization circuit 132 may perform an equalization operation based on the sampling signal PS. The sampling signal PS may be fed back to the decision feedback equalization circuit 132. The decision feedback equalization circuit 132 may cancel a post cursor of the input signal IN based on the sampling signal PS. The decision feedback equalization circuit 132 may receive the plurality of internal clock signals INCLK. The decision feedback equalization circuit 132 may generate the sampling signal PS by comparing the input signal IN with the complementary signal INB in synchronization with the plurality of internal clock signals INCLK. In an embodiment, the decision feedback equalization circuit 132 may further receive a reference voltage VREF. The reference voltage VREF may have a voltage level corresponding to a middle of a swing range of the input signal IN. The decision feedback equalization circuit 132 may generate the sampling signal PS by performing an equalization operation on the input signal IN based on the sampling signal PS and a coefficient. The decision feedback equalization circuit 132 may change the coefficient based on the sampling signal PS. For example, the decision feedback equalization circuit 132 may select one among at least two coefficients based on a logic level of the sampling signal PS and may perform an equalization operation based on the selected coefficient and the sampling signal PS. For example, the decision feedback equalization circuit 132 may perform an equalization operation by utilizing a first coefficient when the sampling signal PS has a first logic level. For example, the decision feedback equalization circuit 132 may perform an equalization operation by utilizing a second coefficient when the sampling signal PS has a second logic level. The decision feedback equalization circuit 132 may generate, together with the sampling signal PS, a complementary signal PSB of the sampling signal PS.

The signal receiving circuit 122 may further include a latch circuit 133. The latch circuit 133 may receive the sampling signal PS and may generate an output signal OUT. The latch circuit 133 may generate the output signal OUT by latching the sampling signal PS. The latch circuit 133 may generate, together with the output signal OUT, a complementary signal OUTB of the output signal OUT.

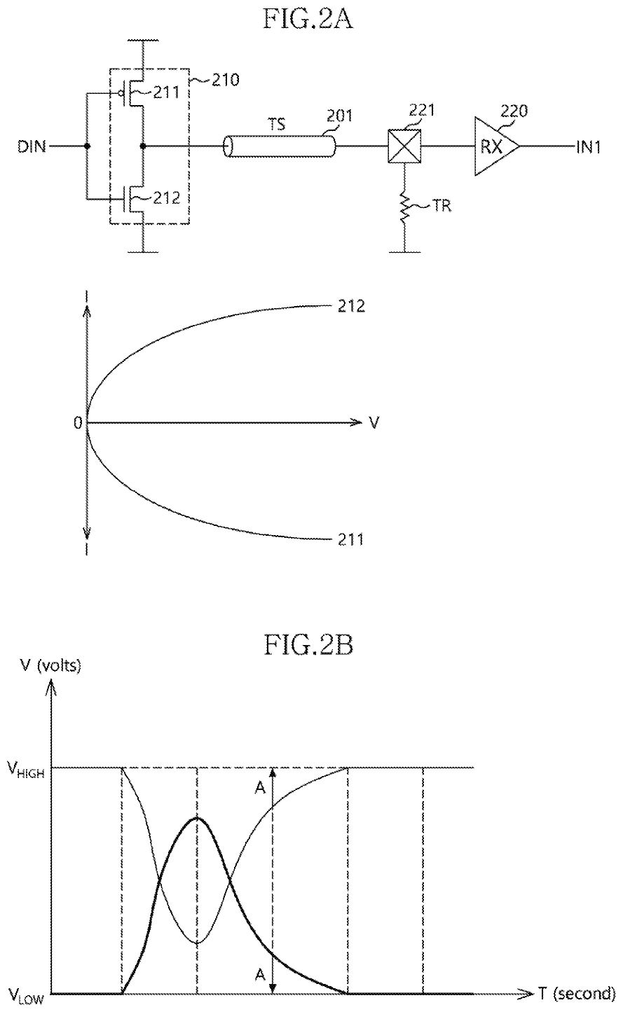

FIG. 2A is a diagram illustrating a configuration of a semiconductor system and a characteristic of an electrical current of a transmission circuit 210 under a symmetric interface circumstance; and FIG. 2B is a diagram illustrating a representation of an example of a waveform of an input signal IN1 generated by a receiver 220 illustrated in FIG. 2A. Referring to FIG. 2A, the semiconductor system may include a transmission circuit 210 and a receiver 220. The transmission circuit 210 may be arranged in the external apparatus 110 and the receiver 220 may be arranged in the semiconductor apparatus 120, as illustrated in FIG. 1. The transmission circuit 210 and the receiver 220 may be electrically coupled to each other through a bus 201. The transmission circuit 210 may transmit the transmission signal TS through the bus 201 by pull-up driving or pull-down driving the bus 201 based on an internal signal DIN. The receiver 220 may be electrically coupled to the bus 201 through a pad 221 and may generate the input signal IN1 from the transmission signal TS. For the impedance matching at a transmission end and a reception end of the transmission signal TS, a termination resistance TR may be electrically coupled to the pad 221. The transmission circuit 210 may have a configuration of “P over N” driver. Within the transmission circuit 210, a pull-up driver for pull-up driving the bus 201 according to the internal signal DIN may be configured with a P channel MOS transistor 211 and a pull-down driver for pull-down driving the bus 201 according to the internal signal DIN may be configured with an N channel MOS transistor 212. The P channel MOS transistor 211 and the N channel MOS transistor 212 may have the same electrical current characteristic since both of the P channel MOS transistor 211 and the N channel MOS transistor 212 can operate within a linear region. Therefore, the bus 201 may be pull-up driven or pull-down driven by the same driving force. As illustrated in FIG. 2B, the input signal IN1 output from the receiver 220 may have a symmetric voltage level regardless of the transition direction of the transmission signal TS. The input signal IN1 transitioning from a logic low level to a logic high level according to the transmission signal TS and the input signal IN1 transitioning from a logic high level to a logic low level according to the transmission signal TS may be symmetrical. For example, at time “T” in FIG. 2B, difference A between the voltage level of a maximum swing level V_{HIGH} of the input signal IN1 and the voltage level of the input signal IN1 transitioned to a logic high level may be the same as difference A between the voltage level of a minimum swing level V_{LOW} of the input signal IN1 and the voltage level of the input signal IN1 transitioned to a logic low level.

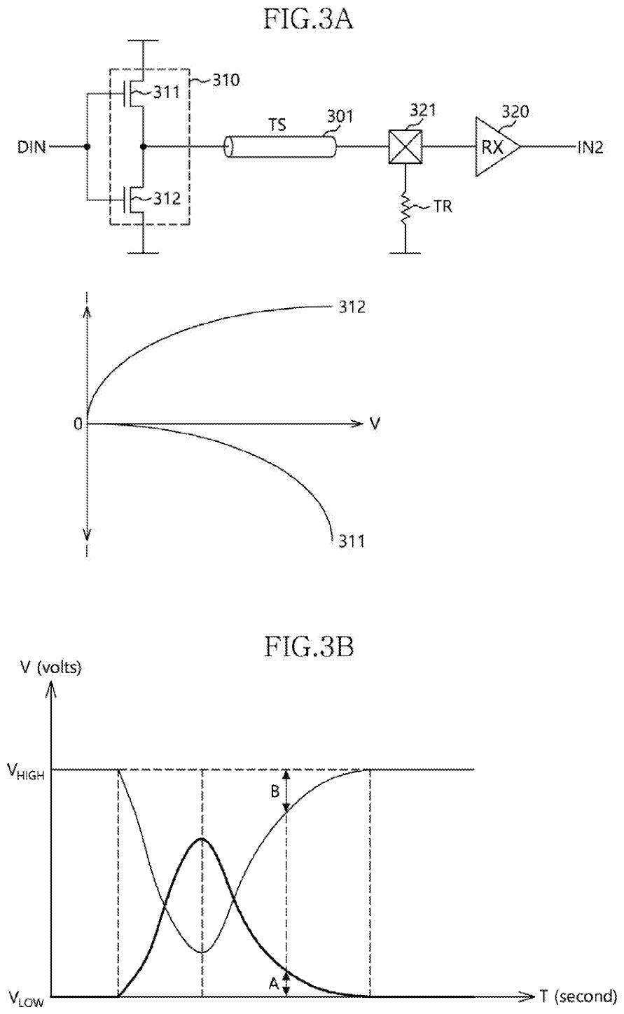

FIG. 3A is a diagram illustrating a configuration of a semiconductor system and a characteristic of an electrical current of a transmission circuit 310 under an asymmetric interface circumstance; and FIG. 3B is a diagram illustrating a waveform of an input signal IN2 generated by a receiver 320 illustrated in FIG. 3A. Referring to FIG. 3A, the semiconductor system may include a transmission circuit 310 and a receiver 320. The transmission circuit 310 may have a configuration of “N over N” driver, which is different from the transmission circuit 210 illustrated in FIG. 2A. The “N over N” driver may be utilized for transmitting a high-speed signal or a signal having a low common mode. Within the transmission circuit 310, a pull-up driver for pull-up driving a bus 301 according to the internal signal DIN may be configured with an N channel MOS transistor 311 and a pull-down driver for pull-down driving the bus 301 according to the internal signal DIN may be configured with an N channel MOS transistor 312. The N channel MOS transistor 312 for pull-down driving the bus 301 may operate within a linear region while the N channel MOS transistor 311 for pull-up driving the bus 301 may operate within a saturation region due to the voltage drop by the threshold voltage of the N channel MOS transistor 311. Therefore, the driving force for pull-up driving the bus 301 may be smaller than the driving force for pull-down driving the bus 301. The receiver 320 may be electrically coupled to the bus 301 through a pad 321 and may generate an input signal IN2 from the transmission signal TS. As illustrated in FIG. 3B, the input signal IN2 output from the receiver 320 may have asymmetric voltage levels to each other according to the transition directions of the transmission signal TS and the input signal IN2. The input signal IN2 transitioning from a logic low level to a logic high level according to the transmission signal TS relatively slowly transitions from a logic low level to a logic high level. On the other hand, the input signal IN2 transitioning from a logic high level to a logic low level according to the transmission signal TS relatively fast transitions from a logic high level to a logic low level. For example, at a time “T” in FIG. 3B, difference (“B”) between the voltage level of a maximum swing level V_{HIGH} of the input signal IN2 and the voltage level of the input signal IN2 transitioned to a logic high level may be greater than difference (“A”) between the voltage level of a minimum swing level V_{LOW} of the input signal IN2 and the voltage level of the input signal IN2 transitioned to a logic low level.

As illustrated in FIGS. 2A to 2B and 3A to 3B, according to the interface circumstance, the waveforms of the transmission signal TS transferred through the bus 102 and the input signal IN generated by the receiver 131 of FIG. 1 may be asymmetrical according to the transition directions of the transmission signal TS and the input signal IN. Furthermore, when the resistance value of the termination resistance TR is not matched to one between the turn-on resistance value of the pull-up driver and the turn-on resistance value of the pull-down driver, the transmission signal TS and the input signal IN may have the waveforms such as illustrated in FIG. 3B. Therefore, under the asymmetric interface circumstance, the signal receiving circuit 122 and the decision feedback equalization circuit 132 illustrated in FIG. 1 need to perform different equalization operations from each other according to the transition direction of the input signal IN.

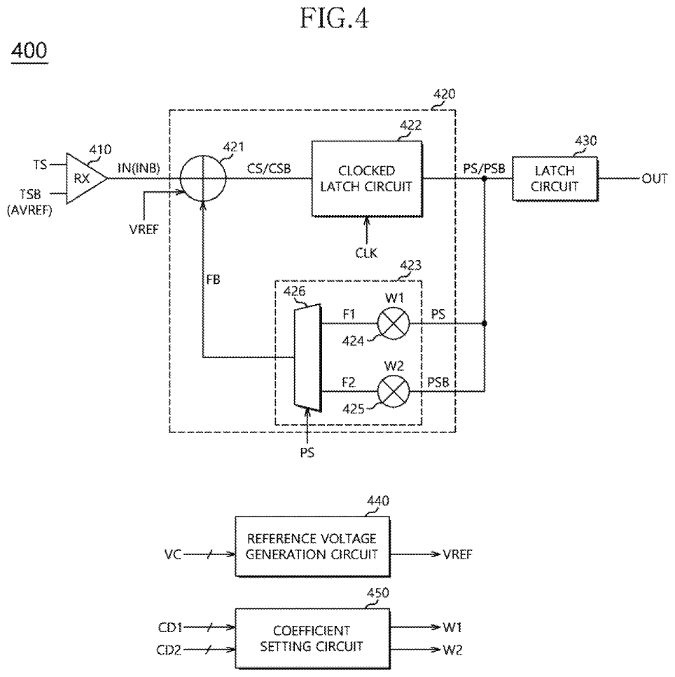

FIG. 4 is a diagram illustrating a configuration of a signal receiving circuit 400 in accordance with an embodiment. The signal receiving circuit 400 may be applied as the signal receiving circuit 122 illustrated in FIG. 1. Referring to FIG. 4, the signal receiving circuit 400 may include a receiver 410 and a decision feedback equalization circuit 420. The receiver 410 may generate an input signal IN based on a transmission signal TS. When the transmission signal TS is provided as a differential signal, the receiver 410 may generate the input signal IN by differentially amplifying the transmission signal TS and a complementary signal TSB of the transmission signal TS. When the transmission signal TS is provided as a single-ended signal, the receiver 410 may generate the input signal IN by differentially amplifying the transmission signal TS and an amplification reference voltage AVREF. In an embodiment, the receiver 410 may output, together with the input signal IN, a complementary signal INB of the input signal IN.

The decision feedback equalization circuit 420 may generate a sampling signal PS by performing an equalization operation on the input signal IN. The decision feedback equalization circuit 420 may include a summing circuit 421, a clocked latch circuit 422 and a feedback circuit 423. The summing circuit 421 may receive the input signal IN and a feedback signal FB. The summing circuit 421 may generate a summing signal CS based on the input signal IN and the feedback signal FB. The summing circuit 421 may generate the summing signal CS based on the input signal IN and may change a voltage level of the summing signal CS based on the feedback signal FB. The summing circuit 421 may generate the summing signal CS by comparing voltage levels of the input signal IN and a reference voltage VREF. The reference voltage VREF may have a voltage level corresponding to a middle of a swing range of the input signal IN. In an embodiment, the summing circuit 421 may generate the summing signal CS by comparing the voltage levels of the input signal IN and the complementary signal INB. The summing circuit 421 may output, together with the summing signal CS, a complementary signal CSB of the summing signal CS. The summing circuit 421 may change the voltage level of the summing signal CS based on the feedback signal FB. In an embodiment, the summing circuit 421 may change the voltage level of the summing signal CS and the complementary signal CSB of the summing signal CS based on the feedback signal FB. The feedback signal FB may be generated by the feedback circuit 423.

The clocked latch circuit 422 may generate the sampling signal PS based on the summing signal CS. The clocked latch circuit 422 may determine a voltage level of the sampling signal PS based on the voltage level of the summing signal CS. The clocked latch circuit 422 may sample the summing signal CS in synchronization with the clock signal CLK and may output the sampled signal as the sampling signal PS. The clocked latch circuit 422 may latch the voltage level of the summing signal CS in synchronization with the clock signal CLK and may output the latched signal as the sampling signal PS. The clocked latch circuit 422 may output, together with the sampling signal PS, a complementary signal PSB of the sampling signal PS.

The feedback circuit 423 may receive the sampling signal PS and may generate the feedback signal FB based on the sampling signal PS. The feedback circuit 423 may receive a first coefficient W1 and a second coefficient W2. The first coefficient W1 and the second coefficient W2 may be weight factors utilized for an equalization operation of the decision feedback equalization circuit 420. The first coefficient W1 and the second coefficient W2 may have different magnitudes from each other. For example, the first coefficient W1 and the second coefficient W2 may be analogue voltage signals having different voltage levels from each other and the voltage level of the second coefficient W2 may be higher than the voltage level of the first coefficient W1. The feedback circuit 423 may select one between the first coefficient W1 and the second coefficient W2 based on the sampling signal PS and may generate the feedback signal FB based on the selected coefficient and the sampling signal PS. The feedback circuit 423 may select the first coefficient W1 when the sampling signal PS has a first logic level, the sampling signal PS being generated on the basis of previously received input signal IN. The feedback circuit 423 may generate the feedback signal FB based on the first coefficient W1 and the sampling signal PS. On the other hand, the feedback circuit 423 may select the second coefficient W2 when the sampling signal PS has a second logic level, the sampling signal PS being generated on the basis of previously received input signal IN. The feedback circuit 423 may generate the feedback signal FB based on the second coefficient W2 and the sampling signal PS. The first logic level may be a logic high level and the second logic level may be a logic low level.

The feedback circuit 423 may include a first multiplier 424, a second multiplier 425 and a selector 426. The first multiplier 424 may receive the first coefficient W1 and the sampling signal PS and may generate a first compensation signal F1 based on the first coefficient W1 and the sampling signal PS. The first multiplier 424 may generate the first compensation signal F1 by performing a multiplication operation on the first coefficient W1 and the sampling signal PS. The second multiplier 425 may receive the second coefficient W2 and the complementary signal PSB of the sampling signal PS and may generate a second compensation signal F2 based on the second coefficient W2 and the complementary signal PSB. The second multiplier 425 may generate the second compensation signal F2 by performing a multiplication operation on the second coefficient W2 and the complementary signal PSB. The selector 426 may receive the first compensation signal F1 and the second compensation signal F2, which are respectively output from the first multiplier 424 and the second multiplier 425, and the sampling signal PS. The selector 426 may output, as the feedback signal FB, one between the first compensation signal F1 and the second compensation signal F2 based on the sampling signal PS. For example, the selector 426 may output, as the feedback signal FB, the first compensation signal F1 generated by the first multiplier 424 when the sampling signal PS has a first logic level. For example, the selector 426 may output, as the feedback signal FB, the second compensation signal F2 generated by the second multiplier 425 when the sampling signal PS has a second logic level.

The signal receiving circuit 400 may further include a latch circuit 430. The latch circuit 430 may generate an output signal OUT based on the sampling signal PS. The latch circuit 430 may latch the sampling signal PS and may output the latched signal as the output signal OUT. The latch circuit 430 may latch, together with the sampling signal PS, the complementary signal PSB and may output, together with the output signal OUT, a complementary signal OUTB of the output signal OUT.

The signal receiving circuit 400 may change the voltage level of the reference voltage VREF based on a swing range of the summing signal CS generated by the summing circuit 421. When the voltage level of the summing signal CS, which is generated on the basis of the input signal IN, is changed on the basis of the feedback signal FB, which is generated by the feedback circuit 423, the common mode of the summing signal CS may become different from the common mode of the input signal IN. Therefore, the signal receiving circuit 400 may change the voltage level of the reference voltage VREF thereby allowing the reference voltage VREF to have a voltage level corresponding to a middle of the swing range of the summing signal CS. The signal receiving circuit 400 may further include a reference voltage generation circuit 440. The reference voltage generation circuit 440 may change the voltage level of the reference voltage VREF based on a voltage control signal VC. The voltage control signal VC may be an arbitrary control signal that can be generated on the basis of the magnitudes or the voltage levels of the first coefficient W1 and the second coefficient W2.

The signal receiving circuit 400 may further include a coefficient setting circuit 450. The coefficient setting circuit 450 may receive a first control signal CD1 and a second control signal CD2 and may generate the first coefficient W1 and the second coefficient W2. The coefficient setting circuit 450 may generate the first coefficient W1 based on the first control signal CD1 and may generate the second coefficient W2 based on the second control signal CD2. The coefficient setting circuit 450 may be a digital-to-analogue converter. The coefficient setting circuit 450 may generate the first coefficient W1 having the voltage level, which changes according to a code value of the first control signal CD1, and may generate the second coefficient W2 having the voltage level, which changes according to a code value of the second control signal CD2. The first control signal CD1 and the second control signal CD2 may be arbitrary control signals that can be generated in consideration of the interface circumstance.

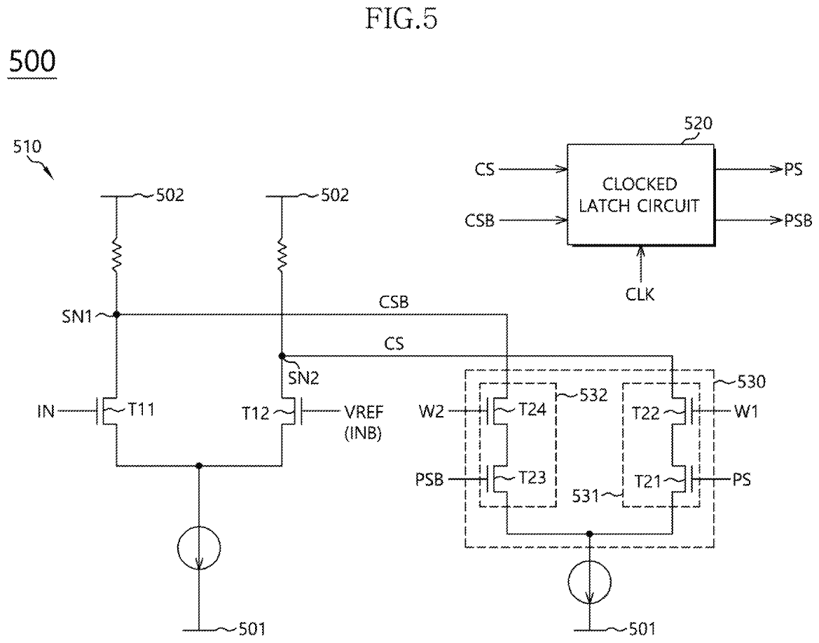

FIG. 5 is a diagram illustrating a configuration of a decision feedback equalization circuit 500 in accordance with an embodiment. The decision feedback equalization circuit 500 may be applied as the decision feedback equalization circuit 420 illustrated in FIG. 4. Referring to FIG. 5, the decision feedback equalization circuit 500 may include a comparison circuit 510, a clocked latch circuit 520 and a feedback circuit 530. The comparison circuit 510 may change voltage levels of a first summing node SN1 and a second summing node SN2 based on the input signal IN and the reference voltage VREF. The comparison circuit 510 may change the voltage levels of the first summing node SN1 and the second summing node SN2 by comparing the input signal IN with the reference voltage VREF. In an embodiment, the comparison circuit 510 may receive the complementary signal INB of the input signal IN instead of the reference voltage VREF. In an embodiment, the comparison circuit 510 may change the voltage levels of the first summing node SN1 and the second summing node SN2 by comparing the input signal IN with the complementary signal INB.

The clocked latch circuit 520 may be electrically coupled to the first summing node SN1 and the second summing node SN2 and may receive a first summing signal CS and a second summing signal CSB. The first summing signal CS may be output from the second summing node SN2 and the second summing signal CSB may be output from the first summing node SN1. The clocked latch circuit 520 may receive a clock signal CLK. The clocked latch circuit 520 may generate the sampling signal PS by sampling the first summing signal CS and the second summing signal CSB in synchronization with the clock signal CLK. The clocked latch circuit 520 may output the sampling signal PS and the complementary signal PSB of the sampling signal PS based on the voltage levels of the first summing signal CS and the second summing signal CSB in synchronization with the clock signal CLK. For example, the clocked latch circuit 520 may generate the sampling signal PS and the complementary signal PSB of the sampling signal PS by latching the voltage levels of the first summing node SN1 and the second summing node SN2 at each rising edge of the clock signal CLK.

The feedback circuit 530 may be electrically coupled to the first summing node SN1 and the second summing node SN2 and may receive the sampling signal PS. The feedback circuit 530 may receive the first coefficient W1 and the second coefficient W2 and may select one between the first coefficient W1 and the second coefficient W2 based on the sampling signal PS. The feedback circuit 530 may change, when the sampling signal PS has a logic high level, the voltage level of the second summing node SN2 based on the first coefficient W1 and the sampling signal PS. The feedback circuit 530 may change, when the sampling signal PS has a logic low level, the voltage level of the first summing node SN1 based on the first second coefficient W2 and the sampling signal PS. The feedback circuit 530 may receive the clock signal CLK and may operate in synchronization with the clock signal CLK. The feedback circuit 530 may change, when the clock signal CLK has a logic high level, the voltage levels of the first summing node SN1 and the second summing node SN2 based on the first coefficient W1, the second coefficient W2 and the sampling signal PS.

The feedback circuit 530 may include a first compensation circuit 531 and a second compensation circuit 532. The first compensation circuit 531 may be electrically coupled to the second summing node SN2 and may change the voltage level of the second summing node SN2 based on the first coefficient W1 and the sampling signal PS. The second compensation circuit 532 may be electrically coupled to the first summing node SN1 and may change the voltage level of the first summing node SN1 based on the second coefficient W2 and the complementary signal PSB of the sampling signal PS.

The comparison circuit 510 may include a first transistor T11 and a second transistor T12. Each of the first transistor T11 and the second transistor T12 may be an N channel MOS transistor. The first transistor T11 may receive the input signal IN at its gate, may be electrically coupled to the first summing node SN1 at its drain and may be electrically coupled to a first power voltage node 501 through a current source at its source. The second transistor T12 may receive the reference voltage VREF at its gate, may be electrically coupled to the second summing node SN2 at its drain and may be electrically coupled to the first power voltage node 501 through the current source at its source. A first power voltage may be provided through the first power voltage node 501. The first summing node SN1 may be electrically coupled to a second power voltage node 502 through a resistive load. The second summing node SN2 may be electrically coupled to the second power voltage node 502 through a resistive load. The resistive loads may have the same resistance value as each other. A second power voltage may be provided through the second power voltage node 502. The second power voltage may have a higher voltage level than the first power voltage.

The feedback circuit 530 may include a first transistor T21, a second transistor T22, a third transistor T23 and a fourth transistor T24. Each of the first to fourth transistors T21, T22, T23 and T24 may be an N channel MOS transistor. The first transistor T21 and the second transistor T22 may configure the first compensation circuit 531 and the third transistor T23 and the fourth transistor T24 may configure the second compensation circuit 532. The first transistor T21 may receive the sampling signal PS at its gate and may be electrically coupled to the first power voltage node 501 through a current source at its source. The second transistor T22 may receive the first coefficient W1 at its gate, may be electrically coupled to the second summing node SN2 at its drain and may be electrically coupled to a drain of the first transistor T21 at its source. The third transistor T23 may receive the complementary signal PSB of the sampling signal PS at its gate and may be electrically coupled to the first power voltage node 501 through the current source at its source. The fourth transistor T24 may receive the second coefficient W2 at its gate, may be electrically coupled to the first summing node SN1 at its drain and may be electrically coupled to a drain of the third transistor T23 at its source.

The first transistor T21 may be turned on and the first compensation circuit 531 may lower the voltage level of the second summing node SN2 according to the voltage level of the first coefficient W1 when the sampling signal PS has a logic high level, the sampling signal PS being generated on the basis of the previously received input signal IN. A greater amount of current may flow through the second transistor T12 of the comparison circuit 510 when the input signal IN has a logic low level. Therefore, the voltage level of the second summing node SN2 may become lower than the voltage level of the first summing node SN1. The feedback circuit 530 may accelerate the lowering of the voltage level of the second summing node SN2 and, relatively, may accelerate the rising of the voltage level of the first summing node SN1. The voltage level of the second summing node SN2 may lower in proportion to the first coefficient W1 and, relatively, the voltage level of the first summing node SN1 may rise in proportion to the first coefficient W1. Therefore, the first summing signal CS may have a lower voltage level than the input signal IN. A greater amount of current may flow through the first transistor T11 of the comparison circuit 510 when the input signal IN has a logic high level. Therefore, the voltage level of the first summing node SN1 may become lower than the voltage level of the second summing node SN2. The feedback circuit 530 may raise the voltage level of the first summing node SN1 in proportion to the first coefficient W1 and may lower the voltage level of the second summing node SN2 in proportion to the first coefficient W1. Therefore, the first summing signal CS may have a lower voltage level than the input signal IN.

The complementary signal PSB of the sampling signal PS generated on the basis of the previously received input signal IN may have a logic high level when the sampling signal PS generated on the basis of the previously received input signal IN has a logic low level. Therefore, the third transistor T23 may be turned on and the second compensation circuit 532 may lower the voltage level of the first summing node SN1 according to the voltage level of the second coefficient W2. A greater amount of current may flow through the first transistor T11 of the comparison circuit 510 when the input signal IN has a logic high level. Therefore, the voltage level of the first summing node SN1 may become lower than the voltage level of the second summing node SN2. The feedback circuit 530 may accelerate the lowering of the voltage level of the first summing node SN1 and, relatively, may accelerate the rising of the voltage level of the second summing node SN2. The voltage level of the first summing node SN1 may lower in proportion to the second coefficient W2 and, relatively, the voltage level of the second summing node SN2 may rise in proportion to the second coefficient W2. The voltage level of the second summing node SN2 may become lower than the voltage level of the first summing node SN1 when the input signal IN has a logic low level. The feedback circuit 530 may raise the voltage level of the first summing node SN1 in proportion to the second coefficient W2 and may lower the voltage level of the second summing node SN2 in proportion to the second coefficient W2. Therefore, the first summing signal CS may have a higher voltage level than the input signal IN.

The decision feedback equalization circuit 500 may generate the first summing signal CS and the second summing signal CSB by performing an equalization operation on the input signal IN as follows. When the input signal IN transitions from a logic high level to a logic low level, the voltage level of the first summing signal CS may lower and the voltage level of the first summing signal CS may additionally lower in proportion to the first coefficient W1. The voltage level of the second summing signal CSB may rise and the voltage level of the second summing signal CSB may additionally rise in proportion to the first coefficient W1. When the input signal IN transitions from a logic low level to a logic high level, the voltage level of the first summing signal CS may rise and the voltage level of the first summing signal CS may additionally rise in proportion to the second coefficient W2. The voltage level of the second summing signal CSB may lower and the voltage level of the second summing signal CSB may additionally lower in proportion to the second coefficient W2.

Further, the voltage level of the first summing signal CS may lower in proportion to the first coefficient W1 when the input signal IN maintains to have a logic high level and the voltage level of the first summing signal CS may rise in proportion to the second coefficient W2 when the input signal IN maintains to have a logic low level. Therefore, the voltage levels of the first summing signal CS and the second summing signal CSB may be asymmetrically compensated according to the logic level of the sampling signal PS.

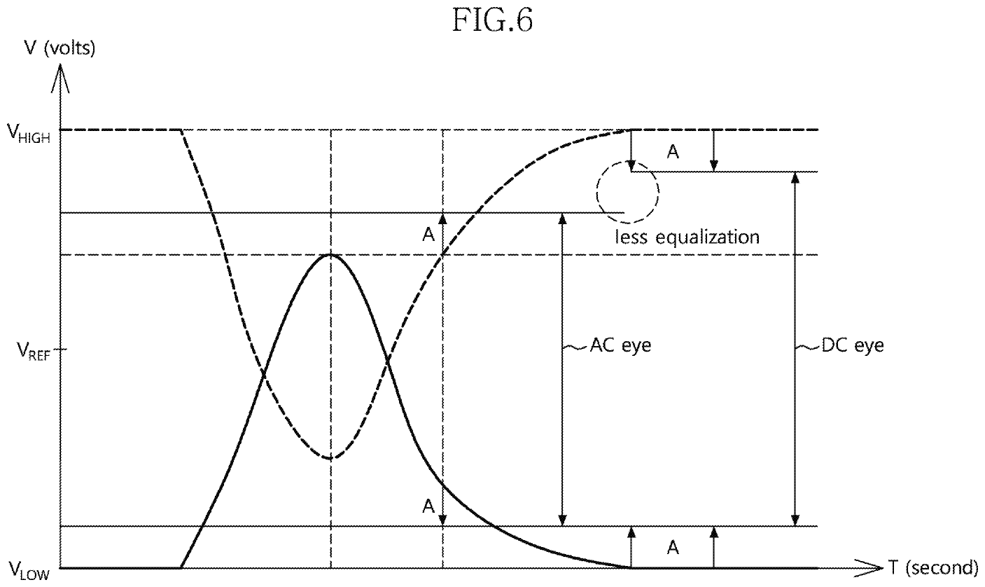

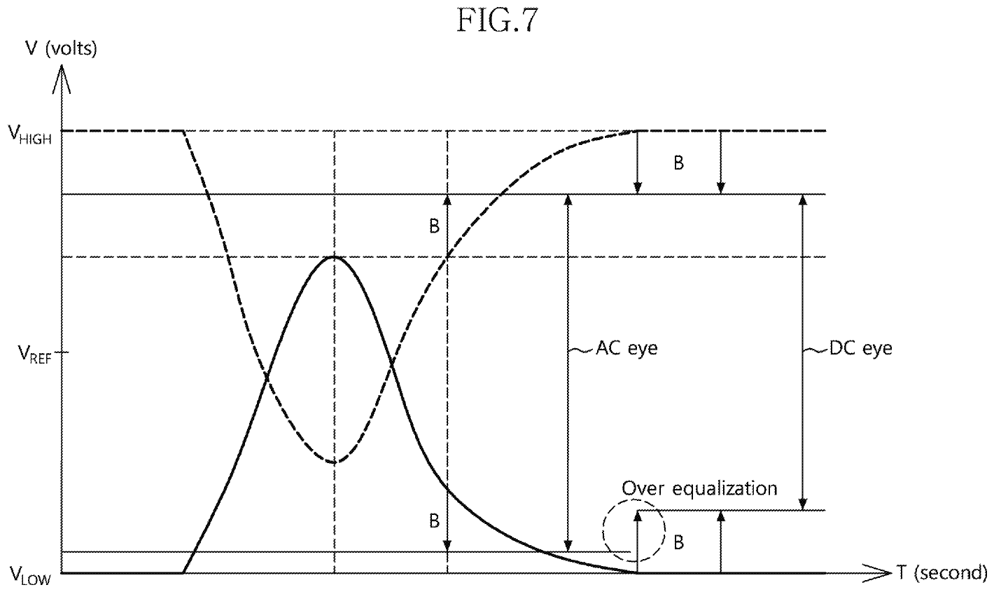

FIGS. 6 and 7 are diagrams illustrating a summing signal when an equalization operation is performed with a single coefficient under an asymmetric interface circumstance. For example, FIG. 6 illustrates a waveform of the first summing signal CS when an equalization operation is performed with the first coefficient W1 and FIG. 7 illustrates a waveform of the first summing signal CS when an equalization operation is performed with the second coefficient W2. Referring to FIG. 6, when the input signal IN transitions from a logic low level to a logic high level and an equalization operation is performed with the first coefficient W1, the voltage level of the first summing signal CS may additionally rise by an amount of A in proportion to the first coefficient W1. When the input signal IN transitions from a logic high level to a logic low level and an equalization operation is performed with the first coefficient W1, the voltage level of the first summing signal CS may additionally lower by an amount of A in proportion to the first coefficient W1. When assumed that the input signal IN is generated on the basis of a signal transmitted through an asymmetrical interface circumstance such as the “N over N” driver illustrated in FIG. 2B, the input signal IN may relatively slowly transition to the logic high level when compared with a case of transition to a logic low level. Therefore, when compensating a voltage level by an amount of A by utilizing a single coefficient, the voltage compensation for the input signal IN may not be sufficient (“less equalization”) when the input signal IN transitions to a logic high level.

When the input signal IN maintains to have a logic low level and an equalization operation is performed with the first coefficient W1, the voltage level of the first summing signal CS may rise by an amount of A. When the input signal IN maintains to have a logic high level and an equalization operation is performed with the first coefficient W1, the voltage level of the first summing signal CS may lower by an amount of A. Difference between the maximum voltage level and the minimum voltage level may be the “AC eye” when the voltage level of the first summing signal CS transitions and difference between the maximum voltage level and the minimum voltage level may be the “DC eye” when the voltage level of the first summing signal CS maintains. When an equalization operation is performed by utilizing only the first coefficient W1, there may occur a mismatch between the “AC eye” and the “DC eye” of the compensated signal and the “AC eye” may become smaller than the “DC eye”.

Referring to FIG. 7, when the input signal IN transitions from a logic low level to a logic high level and an equalization operation is performed with the second coefficient W2, the voltage level of the first summing signal CS may additionally rise by an amount of B in proportion to the second coefficient W2. When the input signal IN transitions from a logic high level to a logic low level and an equalization operation is performed with the second coefficient W2, the voltage level of the first summing signal CS may additionally lower by an amount of B in proportion to the second coefficient W2. When assumed that the input signal IN is generated on the basis of a signal transmitted through an asymmetrical interface circumstance such as the “N over N” driver illustrated in FIG. 2B, the input signal IN may relatively slowly transition to the logic high level when compared with a case of transition to a logic low level. Therefore, when compensating a voltage level by an amount of B by utilizing a single coefficient, the voltage compensation for the input signal IN may be too much (“over equalization”) when the input signal IN transitions to a logic low level.

When the input signal IN maintains to have a logic low level and an equalization operation is performed with the second coefficient W2, the voltage level of the first summing signal CS may rise by an amount of B. When the input signal IN maintains to have a logic high level and an equalization operation is performed with the second coefficient W2, the voltage level of the first summing signal CS may lower by an amount of B. When an equalization operation is performed by utilizing only the second coefficient W2, there may occur a mismatch between the “AC eye” and the “DC eye” of the compensated signal and the “AC eye” may become greater than the “DC eye”. When there occurs the mismatch between the “AC eye” and the “DC eye” as illustrated in FIGS. 6 and 7, reduced may be a sampling margin for generating a sampling signal by latching a summing signal.

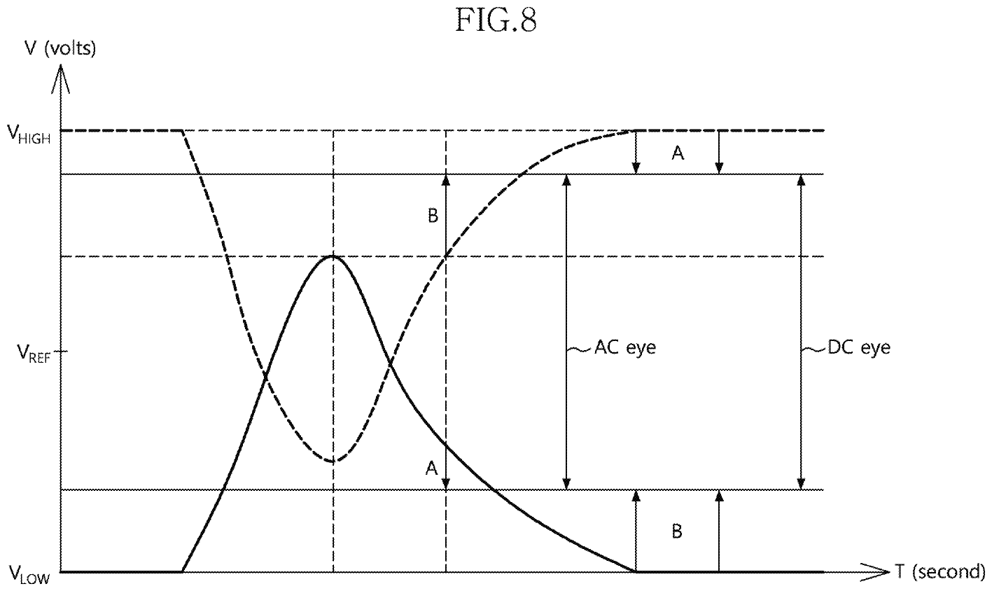

FIG. 8 is a diagram illustrating a summing signal when an equalization operation is performed with different coefficients in accordance with an embodiment. Referring to FIG. 8, when the input signal IN transitions from a logic low level to a logic high level, an equalization operation may be performed with the second coefficient W2 and the voltage level of the summing signal may additionally rise by a sufficient amount of B in proportion to the second coefficient W2. When the input signal IN transitions from a logic high level to a logic low level, an equalization operation may be performed with the first coefficient W1 and the voltage level of the summing signal may additionally lower by an amount of A in proportion to the first coefficient W1 thereby preventing the over equalization. When the input signal IN maintains to have a logic high level, an equalization operation may be performed with the first coefficient W1 and the voltage level of the summing signal may lower in proportion to the first coefficient W1. When the input signal IN maintains to have a logic low level, an equalization operation may be performed with the second coefficient W2 and the voltage level of the summing signal may rise in proportion to the second coefficient W2. Therefore, the “DC eye” and the “AC eye” of the summing signal may become the same as each other and optimized may be the sampling margin of the summing signal.

As illustrated in FIG. 8, when an equalization operation is performed on the summing signal with different coefficients, the voltage level corresponding to a middle of the equalized summing signal may be different from the voltage level of the reference voltage VREF. For example, referring to FIG. 8, the voltage level corresponding to a middle of the equalized summing signal may be higher than the voltage level of the reference voltage VREF. Therefore, the reference voltage generation circuit may change the voltage level of the reference voltage VREF thereby allowing the signal receiving circuit to perform a precise reception operation.

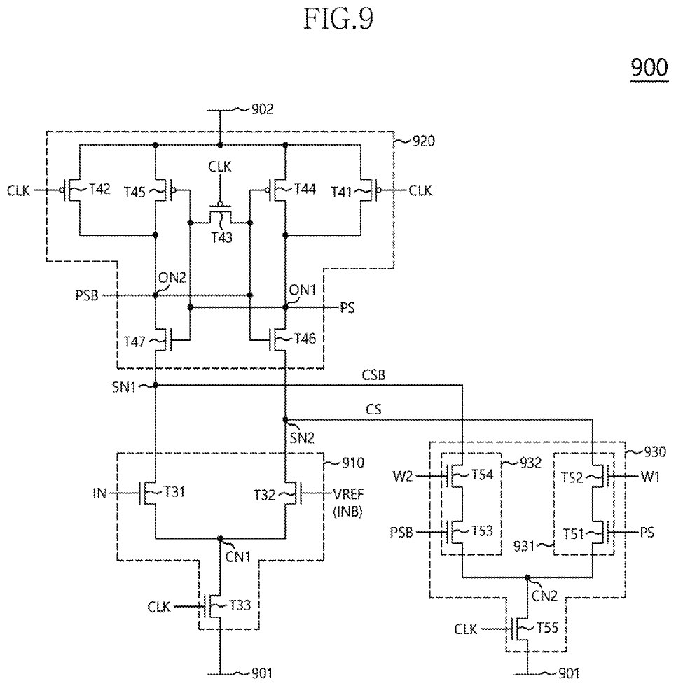

FIG. 9 is a diagram illustrating a configuration of a decision feedback equalization circuit 900 in accordance with an embodiment. The decision feedback equalization circuit 900 may replace the configuration of the decision feedback equalization circuit 420 illustrated in FIG. 4. The decision feedback equalization circuit 900 may include a comparison circuit 910, a clocked latch circuit 920 and a feedback circuit 930. The comparison circuit 910 may receive the input signal IN and the reference voltage VREF and may change the voltage levels of the first summing node SN1 and the second summing node SN2 by comparing voltage levels between the input signal IN and the reference voltage VREF. The complementary signal CSB of the summing signal CS may be output through the first summing node SN1 and the summing signal CS may be output through the second summing node SN2. The comparison circuit 910 may receive the clock signal CLK and may operate in synchronization with the clock signal CLK. The comparison circuit 910 may change, when the clock signal CLK has a logic high level, the voltage levels of the first summing node SN1 and the second summing node SN2 by comparing the voltage levels between the input signal IN and the reference voltage VREF. In an embodiment, the comparison circuit 910 may be modified to be configured to receive the complementary signal INB of the input signal IN instead of the reference voltage VREF.

The clocked latch circuit 920 may be electrically coupled to the first summing node SN1 and the second summing node SN2 and may generate the sampling signal PS based on the voltage levels of the first summing node SN1 and the second summing node SN2. The clocked latch circuit 920 may change the voltage level of the sampling signal PS according to the voltage levels of the first summing node SN1 and the second summing node SN2 and may latch the voltage level of the sampling signal PS. The clocked latch circuit 920 may receive the clock signal CLK and may generate the sampling signal PS in synchronization with the clock signal CLK. The clocked latch circuit 920 may precharge, when the clock signal CLK has a logic low level, the sampling signal PS and the complementary signal PSB of the sampling signal PS. The clocked latch circuit 920 may change the voltage levels of the sampling signal PS and the complementary signal PSB of the sampling signal PS according to the voltage levels of the first summing node SN1 and the second summing node SN2 and may latch the voltage levels of the sampling signal PS and the complementary signal PSB of the sampling signal PS, when the clock signal CLK has a logic high level.

The feedback circuit 930 may be electrically coupled to the first summing node SN1 and the second summing node SN2 and may receive the sampling signal PS. The feedback circuit 930 may receive the first coefficient W1 and the second coefficient W2 and may select one between the first coefficient W1 and the second coefficient W2 based on the sampling signal PS. The feedback circuit 930 may change, when the sampling signal PS has a logic high level, the voltage level of the second summing node SN2 based on the first coefficient W1 and the sampling signal PS. The feedback circuit 930 may change, when the sampling signal PS has a logic low level, the voltage level of the first summing node SN1 based on the second coefficient W2 and the sampling signal PS. The feedback circuit 930 may receive the clock signal CLK and may operate in synchronization with the clock signal CLK. The feedback circuit 930 may change, when the clock signal CLK has a logic high level, the voltage levels of the first summing node SN1 and the second summing node SN2 based on the first coefficient W1, the second coefficient W2 and the sampling signal PS.

The feedback circuit 930 may include a first compensation circuit 931 and a second compensation circuit 932. The first compensation circuit 931 may be electrically coupled to the second summing node SN2 and may change the voltage level of the second summing node SN2 based on the first coefficient W1 and the sampling signal PS. The second compensation circuit 932 may be electrically coupled to the first summing node SN1 and may change the voltage level of the first summing node SN1 based on the second coefficient W2 and the complementary signal PSB of the sampling signal PS.

The comparison circuit 910 may include a first transistor T31, a second transistor T32 and a third transistor T33. Each of the first transistor T31, the second transistor T32 and the third transistor T33 may be a N-channel MOS transistor. The first transistor T31 may be electrically coupled between the first summing node SN1 and a first common node CN1 and may receive the input signal IN at its gate. The second transistor T32 may be electrically coupled between the second summing node SN2 and the first common node CN1 and may receive the reference voltage VREF at its gate. In an embodiment, the second transistor T32 may be modified and/or changed to be configured to receive the complementary signal INB of the input signal IN instead of the reference voltage VREF. The third transistor T33 may be electrically coupled between the first common node CN1 and a first power voltage node 901 and may receive the clock signal CLK at its gate. The first power voltage node 901 may receive a first power voltage. The third transistor T33 may form, when the clock signal CLK has a logic high level, a current path flowing from the first common node CN1 to the first power voltage node 901. Therefore, the comparison circuit 910 may change, when the clock signal CLK has a logic high level, the voltage levels of the first summing node SN1 and the second summing node SN2 by comparing the voltage levels of the input signal IN and the reference voltage VREF. Since an amount of a current flowing through the first transistor T31 becomes greater than an amount of a current flowing through the second transistor T32 when the input signal IN has a logic high level, the voltage level of the first summing node SN1 may become lower than the voltage level of the second summing node SN2. Since an amount of a current flowing through the first transistor T31 becomes smaller than an amount of a current flowing through the second transistor T32 when the input signal IN has a logic low level, the voltage level of the first summing node SN1 may become higher than the voltage level of the second summing node SN2.

The clocked latch circuit 920 may include a first transistor T41, a second transistor T42, a third transistor T43, a fourth transistor T44, a fifth transistor T45, a sixth transistor T46 and a seventh transistor T47. Each of the first to fifth transistors T41, T42, T43, T44 and T45 may be a P channel MOS transistor and each of the sixth and seventh transistors T46 and T47 may be a N channel MOS transistor. The first transistor T41 may be electrically coupled between a second power voltage node 902 and a first output node ON1 and may receive the clock signal CLK at its gate. The second power voltage node 902 may receive a second power voltage, which has a higher voltage level than the first power voltage. The second transistor T42 may be electrically coupled between the second power voltage node 902 and a second output node ON2 may receive the clock signal CLK at its gate. The third transistor T43 may be electrically coupled between the first output node ON1 and the second output node ON2 and may receive the clock signal CLK at its gate. The fourth transistor T44 may be electrically coupled between the second power voltage node 902 and the first output node ON1 and may be electrically coupled to the second output node ON2 at its gate. The fifth transistor T45 may be electrically coupled between the second power voltage node 902 and the second output node ON2 and may be electrically coupled to the first output node ON1 at its gate. The sixth transistor T46 may be electrically coupled between the first output node ON1 and the second summing node SN2 and may be electrically coupled to the second output node ON2 at its gate. The seventh transistor T47 may be electrically coupled between the second output node ON2 and the first summing node SN1 and may be electrically coupled to the first output node ON1 at its gate. The first to third transistors T41, T42 and T43 may perform a precharge operation. The first transistor T41 and the second transistor T42 may precharge, when the clock signal CLK has a logic low level, the first output node ON1 and the second output node ON2 to the second power voltage, respectively. The third transistor T43 may keep, when the clock signal CLK has a logic low level, the voltage levels of the first output node ON1 and the second output node ON2 to the same voltage level by electrically coupling the first output node ON1 and the second output node ON2 to each other.

When the clock signal CLK has a logic high level, the first to third transistors T41, T42 and T43 may be turned off and the fourth to seventh transistors T44, T45, T46 and T47 may perform a latch operation. When the comparison circuit 910 receives the input signal IN and the voltage level of the first summing node SN1 becomes higher than the voltage level of the second summing node SN2, an amount of a current flowing through the seventh transistor T47 may become smaller than an amount of a current flowing through the sixth transistor T46. Therefore, the voltage level of the first output node ON1 may become lower than the voltage level of the second output node ON2 and the fifth transistor T45 may drive the voltage level of the second output node ON2 to the second power voltage. The sixth transistor T46 may keep a current flowing from the first output node ON1 to the second summing node SN2 based on the voltage level of the second output node ON2. Therefore, the sampling signal PS having a logic low level may be output from the first output node ON1 and the complementary signal PSB of the sampling signal PS may be output from the second output node ON2, the complementary signal PSB having a logic high level.

When the comparison circuit 910 receives the input signal IN and the voltage level of the first summing node SN1 becomes lower than the voltage level of the second summing node SN2, an amount of a current flowing through the seventh transistor T47 may become greater than an amount of a current flowing through the sixth transistor T46. Therefore, the voltage level of the second output node ON2 may become lower than the voltage level of the first output node ON1 and the fourth transistor T44 may drive the voltage level of the first output node ON1 to the second power voltage. The seventh transistor T47 may keep a current flowing from the second output node ON2 to the first summing node SN1 based on the voltage level of the first output node ON1. Therefore, the sampling signal PS having a logic high level may be output from the first output node ON1 and the complementary signal PSB of the sampling signal PS may be output from the second output node ON2, the complementary signal PSB having a logic low level.

The feedback circuit 930 may include a first transistor T51, a second transistor T52, a third transistor T53, a fourth transistor T54 and a fifth transistor T55. Each of the first to fifth transistors T51, T52, T53, T54 and T55 may be a N channel MOS transistor. The first transistor T51 and the second transistor T52 may configure the first compensation circuit 931 and may be electrically coupled in series between the second summing node SN2 and the second common node CN2. The first transistor T51 may receive the first coefficient W1 at its gate and the second transistor T52 may receive the sampling signal PS at its gate. The third transistor T53 and the fourth transistor T54 may configure the second compensation circuit 932 and may be electrically coupled in series between the first summing node SN1 and the second common node CN2. The third transistor T53 may receive the second coefficient W2 at its gate and the fourth transistor T54 may receive the complementary signal PSB of the sampling signal PS at its gate. The fifth transistor T55 may be electrically coupled between the second common node CN2 and the first power voltage node 901 and may receive the clock signal CLK at its gate. The fifth transistor T55 may form, when the clock signal CLK has a logic high level, a current path flowing from the second common node CN2 to the first power voltage node 901. Therefore, the feedback circuit 930 may change the voltage level of the second summing node SN2 based on the first coefficient W1 and the sampling signal PS or may change the voltage level of the first summing node SN1 based on the second coefficient W2 and the complementary signal PSB of the sampling signal PS, when the clock signal CLK has a logic high level.

When the sampling signal PS that is generated on the basis of the previously received input signal IN has a logic high level, the first compensation circuit 931 may lower the voltage level of the second summing node SN2 according to the voltage level of the first coefficient W1. When the sampling signal PS that is generated on the basis of the previously received input signal IN has a logic low level, the complementary signal PSB of the sampling signal PS that is generated on the basis of the previously received input signal IN has a logic high level and thus the second compensation circuit 932 may lower the voltage level of the first summing node SN1 according to the voltage level of the second coefficient W2. When the input signal IN transitions from a logic high level to a logic low level, an equalization operation may be performed such that the voltage level of the first output node ON1 additionally lowers in proportion to the first coefficient W1. When the input signal IN transitions from a logic low level to a logic high level, an equalization operation may be performed such that the voltage level of the first output node ON1 additionally rises in proportion to the second coefficient W2. When the input signal IN keeps having a logic high level, an equalization operation may be performed such that the voltage level of the first output node ON1 lowers in proportion to the first coefficient W1. When the input signal IN keeps having a logic low level, an equalization operation may be performed such that the voltage level of the first output node ON1 rises in proportion to the second coefficient W2. Therefore, the voltage level of the first output node ON1 may be asymmetrically compensated according to the logic level of the sampling signal PS.

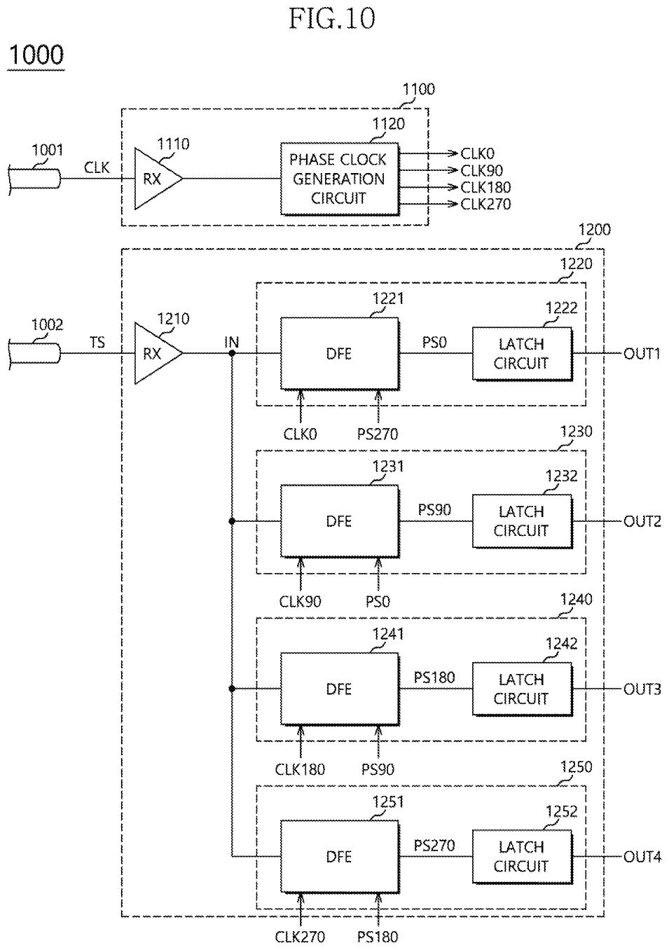

FIG. 10 is a diagram illustrating a configuration of a semiconductor apparatus 1000 in accordance with an embodiment. Referring to FIG. 10, the semiconductor apparatus 1000 may include an internal clock generation circuit 1100 and a signal receiving circuit 1200. The internal clock generation circuit 1100 may receive a clock signal CLK from an external apparatus and may generate a plurality of phase clock signals based on the clock signal CLK. The clock signal CLK may be transmitted through a clock bus 1001 configured to electrically couple the semiconductor apparatus 1000 to the external apparatus. The clock signal CLKE may be buffered by a clock buffer 1110 and the buffered clock signal CLK may be provided to a phase clock generation circuit 1120. The phase clock generation circuit 1120 may generate the plurality of phase clock signals based on the output of the clock buffer 1110. For example, the phase clock generation circuit 1120 may divide the output of the clock buffer 1110 and may generate the plurality of phase clock signal having different phases from one another. The phase clock generation circuit 1120 may generate a first phase clock signal CLK0, a second phase clock signal CLK90, a third phase clock signal CLK180 and a fourth phase clock signal CLK 270. The first phase clock signal CLK0 may have a phase leading the second phase clock signal CLK90 by an amount of 90 degrees, the second phase clock signal CLK90 may have a phase leading the third phase clock signal CLK180 by an amount of 90 degrees, the third phase clock signal CLK180 may have a phase leading the fourth phase clock signal CLK 270 by an amount of 90 degrees and the fourth phase clock signal CLK 270 may have a phase leading the first phase clock signal CLK0 by an amount of 90 degrees.

The signal receiving circuit 1200 may be electrically commonly coupled to a signal bus 1002 electrically coupled to an external apparatus and may receive a transmission signal TS transmitted through the signal bus 1002. The signal receiving circuit 1200 may receive the transmission signal TS through a receiver 1210. The receiver 1210 may generate an input signal IN by comparing the transmission signal TS with a differential signal TSB of the transmission signal TS or an amplification reference voltage AVREF. The signal receiving circuit 1200 may include a plurality of reception paths. A number of the reception paths may correspond to a number of the phase clock signals generated by the phase clock generation circuit 1120. The signal receiving circuit 1200 may include a first reception path 1220, a second reception path 1230, a third reception path 1240 and a fourth reception path 1250. The first reception path 1220 may generate a first output signal OUT1 from the input signal IN based on the first phase clock signal CLK0. The first reception path 1220 may generate a first sampling signal PS0 by sampling the input signal IN in synchronization with the first phase clock signal CLK0 and may generate the first output signal OUT1 by latching the first sampling signal PS0. The second reception path 1230 may generate a second output signal OUT2 from the input signal IN based on the second phase clock signal CLK90. The second reception path 1230 may generate a second sampling signal PS90 by sampling the input signal IN in synchronization with the second phase clock signal CLK90 and may generate the second output signal OUT2 by latching the second sampling signal PS90. The second reception path 1230 may perform an equalization operation through a feedback of the first sampling signal PS0. The third reception path 1240 may generate a third output signal OUT3 from the input signal IN based on the third phase clock signal CLK180. The third reception path 1240 may generate a third sampling signal PS180 by sampling the input signal IN in synchronization with the third phase clock signal CLK180 and may generate the third output signal OUT3 by latching the third sampling signal PS180. The third reception path 1240 may perform an equalization operation through a feedback of the second sampling signal PS90. The fourth reception path 1250 may generate a fourth output signal OUT4 from the input signal IN based on the fourth phase clock signal CLK270. The fourth reception path 1250 may generate a fourth sampling signal PS270 by sampling the input signal IN in synchronization with the fourth phase clock signal CLK270 and may generate the fourth output signal OUT4 by latching the fourth sampling signal PS270. The fourth reception path 1250 may perform an equalization operation through a feedback of the third sampling signal PS180. The first reception path 1220 may perform an equalization operation through a feedback of the fourth sampling signal PS270.

The first reception path 1220 may include a first decision feedback equalization circuit (DFE) 1221 and a first latch circuit 1222. The first decision feedback equalization circuit 1221 may generate the first sampling signal PS0 from the input signal IN in synchronization with the first phase clock signal CLK0. The first decision feedback equalization circuit 1221 may receive the fourth sampling signal P270 and may perform an equalization operation on the input signal IN based on the fourth sampling signal P270. The first latch circuit 1222 may generate the first output signal OUT1 by latching the first sampling signal PS0.

The second reception path 1230 may include a second decision feedback equalization circuit (DFE) 1231 and a second latch circuit 1232. The second decision feedback equalization circuit 1231 may generate the second sampling signal PS90 from the input signal IN in synchronization with the second phase clock signal CLK90. The second decision feedback equalization circuit 1231 may receive the first sampling signal PS0 and may perform an equalization operation on the input signal IN based on the first sampling signal PS0. The second latch circuit 1232 may generate the second output signal OUT2 by latching the second sampling signal PS90.

The third reception path 1240 may include a third decision feedback equalization circuit (DFE) 1241 and a third latch circuit 1242. The third decision feedback equalization circuit 1241 may generate the third sampling signal PS180 from the input signal IN in synchronization with the third phase clock signal CLK180. The third decision feedback equalization circuit 1241 may receive the second sampling signal PS90 and may perform an equalization operation on the input signal IN based on the second sampling signal PS90. The third latch circuit 1242 may generate the third output signal OUT3 by latching the third sampling signal PS180.

The fourth reception path 1250 may include a fourth decision feedback equalization circuit (DFE) 1251 and a fourth latch circuit 1252. The fourth decision feedback equalization circuit 1251 may generate the fourth sampling signal PS270 from the input signal IN in synchronization with the fourth phase clock signal CLK270. The fourth decision feedback equalization circuit 1251 may receive the third sampling signal PS180 and may perform an equalization operation on the input signal IN based on the third sampling signal PS180. The fourth latch circuit 1252 may generate the fourth output signal OUT4 by latching the fourth sampling signal PS270. Each of the first to fourth decision feedback equalization circuits 1221, 1231, 1241 and 1251 may be configured substantially the same as any one among the decision feedback equalization circuits 420, 500 and 900 respectively illustrated in FIGS. 4, 5 and 9.

While certain embodiments have been described above, it will be understood to those skilled in the art that the embodiments described are by way of example only. Accordingly, the signal receiving circuit, semiconductor apparatus and semiconductor system including the same should not be limited based on the described embodiments. Rather, the signal receiving circuit, semiconductor apparatus and semiconductor system including the same described herein should only be limited in light of the claims that follow when taken in conjunction with the above description and accompanying drawings.

1. A signal receiving circuit comprising:
a summing circuit configured to generate a summing signal based on an input signal and a feedback signal;
a clocked latch circuit configured to generate a sampling signal by sampling the summing signal in synchronization with a clock signal; and
a feedback circuit configured to select one between a first coefficient and a second coefficient having a different value from the first coefficient based on a logic level of the sampling signal that is generated on a basis of a previously received input signal and configured to generate the feedback signal based on a selected coefficient and the sampling signal.

2. The signal receiving circuit of claim 1, wherein the summing circuit is configured to generate the summing signal based on the input signal and a reference voltage and configured to change a voltage level of the summing signal based on the feedback signal.

3. The signal receiving circuit of claim 2,
further comprising a reference voltage generation circuit configured to generate the reference voltage,
wherein a voltage level of the reference voltage is determined on a basis of at least one among the first coefficient, the second coefficient, and a swing range of the summing signal.

4. The signal receiving circuit of claim 1, wherein the summing circuit is configured to generate the summing signal and a complementary of the summing signal based on the input signal and a complementary signal of the input signal and configured to change a voltage level of the summing signal and the complementary of the summing signal based on the feedback signal.

5. The signal receiving circuit of claim 1, wherein the feedback circuit is configured to:
generate the feedback signal based on the first coefficient and the sampling signal when the sampling signal that is generated on a basis of the previously received input signal has a first logic level, and
generate the feedback signal based on the second coefficient and the sampling signal when the sampling signal that is generated on a basis of the previously received input signal has a second logic level.

6. The signal receiving circuit of claim 5, wherein the second coefficient has a greater value than the first coefficient.

7. The signal receiving circuit of claim 5, wherein the first and second coefficients are analogue voltage signals having different voltage levels from each other.

8. The signal receiving circuit of claim 1, wherein the feedback circuit includes:
a first multiplier configured to generate a first compensation signal based on the first coefficient and the sampling signal;
a second multiplier configured to generate a second compensation signal based on the second coefficient and the sampling signal; and
a selector configured to output, as the feedback signal, one between the first compensation signal and the second compensation signal based on the sampling signal.

9. The signal receiving circuit of claim 1, further comprising a coefficient setting circuit configured to set a voltage level of the first coefficient based on a first control signal and configured to set a voltage level of the second coefficient based on a second control signal.

10. The signal receiving circuit of claim 1, further comprising a receiver configured to generate the input signal by differentially amplifying a transmission signal transmitted through a signal bus and an amplification reference voltage.

11. The signal receiving circuit of claim 1, further comprising a latch circuit configured to generate an output signal by latching the sampling signal.

12. A signal receiving circuit comprising:
a receiver configured to generate an input signal based on a transmission signal transmitted through a signal bus;
a comparison circuit configured to change a voltage level of a first summing node based on a voltage level of the input signal and configured to change a voltage level of a second summing node based on a voltage level of a reference voltage;
a clocked latch circuit configured to generate a sampling signal by latching the voltage levels of the first summing node and the second summing node in synchronization with a clock signal; and
a feedback circuit configured to select a first coefficient based on the sampling signal when the input signal transitions from a logic high level to a logic low level and select a second coefficient having a greater value than the first coefficient based on the sampling signal when the input signal transitions from a logic low level to a logic high level, and configured to change the voltage levels of the first summing node and the second summing node based on a selected coefficient and the sampling signal.

13. The signal receiving circuit of claim 12, wherein the first and second coefficients are analogue voltage signals having different voltage levels from each other.

14. The signal receiving circuit of claim 13,
wherein the second coefficient has a higher voltage level than the first coefficient, and
wherein the feedback circuit is configured to change the voltage level of the second summing node based on the first coefficient and the sampling signal when the sampling signal has a first logic level, and configured to change the voltage level of the first summing node based on the second coefficient and the sampling signal when the sampling signal has a second logic level.

15. The signal receiving circuit of claim 13, wherein the feedback circuit includes:
a first compensation circuit configured to change the voltage level of the second summing node based on the first coefficient and the sampling signal; and
a second compensation circuit configured to change the voltage level of the first summing node based on the second coefficient and a complementary signal of the sampling signal.

16. The signal receiving circuit of claim 13, further comprising a coefficient setting circuit configured to set a voltage level of the first coefficient based on a first control signal and configured to set a voltage level of the second coefficient based on a second control signal.

17. The signal receiving circuit of claim 13,
further comprising a reference voltage generation circuit configured to generate the reference voltage,
wherein a voltage level of the reference voltage is determined on a basis of at least one among the first coefficient, the second coefficient and a swing range of the summing signal.

18. A signal receiving circuit comprising:
a receiver configured to generate an input signal based on a transmission signal transmitted through a signal bus;
a summing circuit configured to generate a summing signal based on the input signal and a feedback signal;
a clocked latch circuit configured to generate a first sampling signal by sampling the summing signal in synchronization with a first phase clock signal; and
a feedback circuit configured to select one between a first coefficient and a second coefficient having a different value from the first coefficient based on a second sampling signal, which is generated in synchronization with a second phase clock signal having a phase leading the first phase clock signal, and configured to generate the feedback signal based on a selected coefficient and the second sampling signal.

19. The signal receiving circuit of claim 18, wherein the summing circuit is configured to generate the summing signal by comparing the input signal with a reference voltage and configured to change a voltage level of the summing signal based on the feedback signal.

20. The signal receiving circuit of claim 19,
further comprising a reference voltage generation circuit configured to generate the reference voltage,
wherein a voltage level of the reference voltage is determined on a basis of at least one among the first coefficient, the second coefficient and a swing range of the summing signal.

21. The signal receiving circuit of claim 18, wherein the feedback circuit is configured to:
generate the feedback signal based on the first coefficient and the second sampling signal when the second sampling signal has a first logic level, and
generate the feedback signal based on the second coefficient and the second sampling signal when the second sampling signal has a second logic level.

22. The signal receiving circuit of claim 21, wherein the second coefficient has a greater value than the first coefficient.

23. The signal receiving circuit of claim 18, wherein the feedback circuit includes:
a first multiplier configured to generate a first compensation signal based on the first coefficient and the second sampling signal;
a second multiplier configured to generate a second compensation signal based on the second coefficient and the second sampling signal; and
a selector configured to output, as the feedback signal, one between the first compensation signal and the second compensation signal based on the second sampling signal.

24. The signal receiving circuit of claim 18, further comprising a coefficient setting circuit configured to set a voltage level of the first coefficient based on a first control signal and configured to set a voltage level of the second coefficient based on a second control signal.
